(19) United States
(12) Patent Application Publication
(10) Pub. No.: US 2018/0006352 A1
(43) Pub. Date: Jan. 4, 2018

(54) Differential Directional Coupler, Signal Conversion System and Method for Converting a Differential Input Signal

(71) Applicant: Infineon Technologies AG, Neubiberg (DE)

(72) Inventors: Vadim Issakov, Muenchen (DE); Johann Peter Forstner, Steinhoering (DE)

(21) Appl. No.: 15/637,224

(22) Filed: Jun. 29, 2017

(30) Foreign Application Priority Data
Jun. 29, 2016 (DE) 102016111887.7

(51) Int. Cl. H01P 5/18; H03F 3/195; H01P 5/16; H01L 23/64; H01F 27/28; H03H 11/16; G01R 33/36

(52) U.S. Cl. CPC H01P 5/18; H03H 11/16; H03F 3/195; G01R 33/365; H01L 23/645; H01F 27/28; H01P 5/16

(57) ABSTRACT

In accordance with an embodiment, a differential directional coupler includes a first coupler having a first transformer comprising a first input coil and a first output coil, and a second coupler having a second transformer comprising a second input coil and a second output coil. The first input coil and the second input coil each include an input port, the first transformer at least partially covers the second transformer in a top view from a vertical direction onto the differential directional coupler, and the first input coil and the second input coil are configured to be mirror symmetric with respect to one another in the top view with respect to their input ports.

This application claims priority to German patent application No. 102016111887.7, filed on Jun. 29, 2016, which application is hereby incorporated herein by reference in its entirety.

### TECHNICAL FIELD

The present application relates to differential directional couplers, signal conversion systems and corresponding methods for converting a differential input signal.

### BACKGROUND

In radio frequency (RF) systems, for example, a chip based quadrature generation, also called I/Q generation, may be required in order to make possible, for example, an efficient performance of modulation techniques for communication applications or unambiguous phase evaluations for radar applications. In the case of a quadrature generation, a signal is divided into a first and a second signal having, within production tolerances, identical power and a 90° phase difference or a 90° phase shift, respectively. A quadrature generation may be required, for example, for a quadrature amplitude modulation. A quadrature generation requires components which provide an equivalent, particularly halved division of the power of a signal in conjunction with a 90° phase difference. Such components, which provide a 90° phase difference with equivalent, particularly halved and/or uniform power distribution are also called quadrature hybrid directional couplers.

To this is added that the use of differential signals at chip level may be desirable due to the increased insensitivity to interference, better common mode interference suppression, reduced second order nonlinearities and improved stability. Accordingly, it may be required to implement not only a uniform division of power with 90° phase shift between the first and the second signal but, instead, a so called four phase division of a differential input signal having the phases (0°, 180°) into two differential output signals divided uniformly in their power with the phases of (0°, 90°, 180°, 270°).

One possibility for implementing such a four phase division is the use of a voltage controlled oscillator (VCO) which oscillates at double the frequency of the input signal, and a static frequency divider which provides all four phases. This option can scarcely be considered for circuits in the millimeter wave frequency range. For example, a 60 GHz input signal would require oscillators and frequency dividers which can be operated at 120 GHz. In an alternative solution, it is possible to use a so called branch line coupler which is differentially extended. However, this would require a very large chip area, for example 600 μm×200 μM with an input signal having a frequency of 60 GHz. In this case, the I/Q generation in a so called phased array system which is used, for example in mobile radio stations, in broadcast transmitters and at radar installations, would greatly dominate the chip area due to the long wavelength of the input signal. A further possibility would be the use of polyphase filters which, although they can have a small size, can lead to high signal attenuation in a 50Ω system. In addition, a coupler can be used which is based on concentrated elements with a so called lattice lumped element coupler. However, such a coupler holds the great disadvantage that it has a very narrow bandwidth and additional components are required such as, for example, additional circuitry for a coil or a transformer, respectively.

### SUMMARY

In accordance with an embodiment, a differential directional coupler includes a first coupler having a first transformer comprising a first input coil and a first output coil, and a second coupler having a second transformer comprising a second input coil and a second output coil. The first input coil and the second input coil each include an input port, the first transformer at least partially covers the second transformer in a top view from a vertical direction onto the differential directional coupler, and the first input coil and the second input coil are configured to be mirror symmetric with respect to one another in the top view with respect to their input ports.

### BRIEF DESCRIPTION OF THE DRAWINGS

To provide a comprehensive understanding of embodiments and their advantages, reference is made to the following descriptions in conjunction with the attached drawings.

In this context:

FIG. 1 shows an embodiment of a signal conversion system;

FIGS. 2A, 2B, 3 and 4 show embodiments of a differential directional coupler;

FIGS. 5, 6 show equivalent circuits of a differential directional coupler and of a coupler of a differential directional coupler;

FIG. 7A shows an embodiment of a method for converting a differential input signal;

FIG. 7B shows an embodiment for providing a differential directional coupler;

FIGS. 8A, 8B, 9A and 9B show simulations for operating a coupler or a differential directional coupler, respectively; and

FIGS. 10, 11A and 11B show embodiments and simulations of alternative couplers and alternative differential directional couplers.

### DETAILED DESCRIPTION OF ILLUSTRATIVE EMBODIMENTS

In the following, the various embodiments of a differential directional coupler, of a signal conversion system and of a method for converting a differential input signal are described with reference to the attached drawings. Identical, similar or identically acting elements are provided with the same or similar reference symbols.

In some embodiments, the signal conversion system comprises a differential directional coupler described herein. Furthermore, the method is performed in some embodiments by means of a differential directional coupler as described herein and/or by means of a signal conversion system as described herein. That is to say all features disclosed for the differential directional coupler are also disclosed for the signal conversion system and/or the method, and vice versa.

In various differential directional couplers having a small size are provided, and signal conversion systems with differential directional couplers and are achieved. In some embodiments, providing improved methods for converting a differential input signal are also achieved.

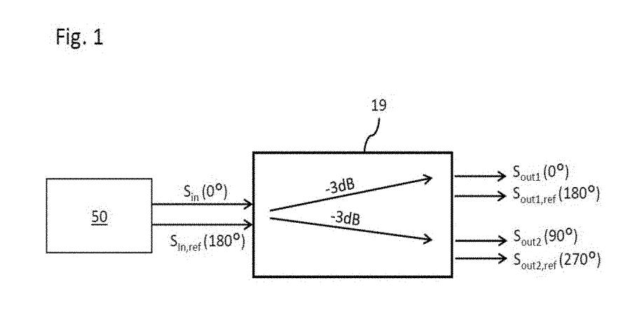

By means of FIG. 1, an embodiment of a signal conversion system, described herein, with a differential directional coupler 19 is explained in greater detail. Purely as an example, a signal conversion system having a differential directional coupler 19 which is designed as quadrature hybrid directional coupler is shown here.

The signal conversion system shown may comprise in each case a transmitter 50 and a directional coupler 19. The transmitter 50 may be configured to generate a differential input signal Sᵢₙ, S_{in,ref} with a base signal Sᵢₙ and a reference signal S_{in,ref}. The reference signal S_{in,ref} may run in opposite phase, that is to say phase shifted by 180°, from the base signal Sᵢₙ. In particular, the reference signal S_{in,ref} may correspond to the base signal Sᵢₙ phase shifted by 180°. The base signal Sᵢₙ may be a non-inverted signal or a positive signal, respectively, and the reference signal S_{in,ref} may be an inverted or a negative signal, respectively. The directional coupler 19 may be configured to convert the differential input signal Sᵢₙ, S_{in,ref} into a first differential output signal Sₒᵤₜ₁, S_{out1,ref} and a second differential output signal Sₒᵤₜ₂, S_{out2,ref}.

In some embodiments, second differential output signal Sₒᵤₜ₂, S_{out2,ref} may be phase shifted, particularly phase shifted by 90°, from differential input signal Sᵢₙ, S_{in,ref} and/or from first differential output signal Sₒᵤₜ₁, S_{out1,ref}. Differential directional coupler 19 may then have a (0°, 90°) phase output and a (180°, 270°) phase output. Furthermore, first differential output signal Sₒᵤₜ₁, S_{out1,ref} and second differential output signal Sₒᵤₜ₂, S_{out2,ref} may have the same power within production tolerances of differential directional coupler 19. For example, differential directional coupler 19 splits the differential input signal Sᵢₙ, S_{in,ref}, within production tolerances, by in each case 50% (corresponding to 3 dB power division) into first differential output signal Sₒᵤₜ₁, S_{out1,ref} and second differential output signal Sₒᵤₜ₂, S_{out2,ref}. For example, the two differential output signals Sₒᵤₜ₁, S_{out1,ref}, Sₒᵤₜ₂, S_{out2,ref} may be local oscillator (LO) signals which may be used for providing quadrature signals, also called I/Q signals. Furthermore, the two differential output signals Sₒᵤₜ₁, S_{out1,ref}, Sₒᵤₜ₂, S_{out2,ref} may be so called quadrature signals which may be suitable for performing a quadrature amplitude modulation process.

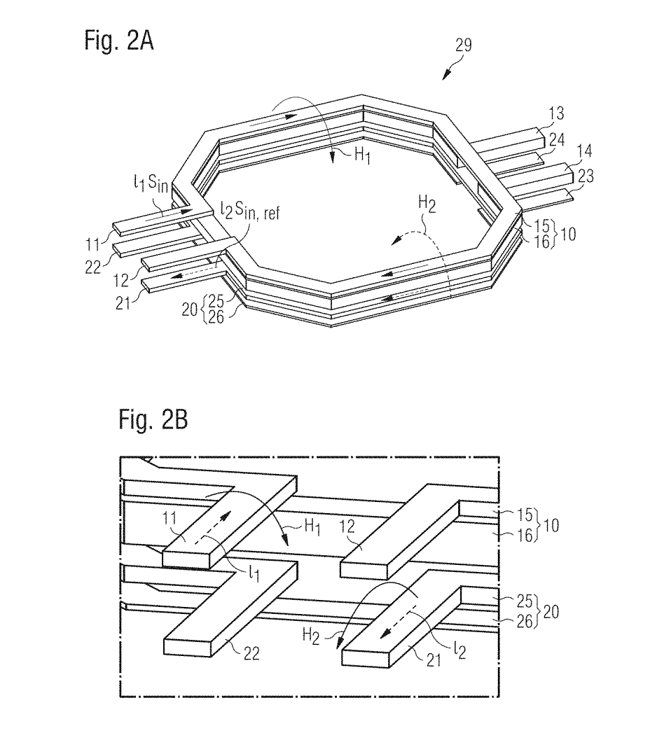

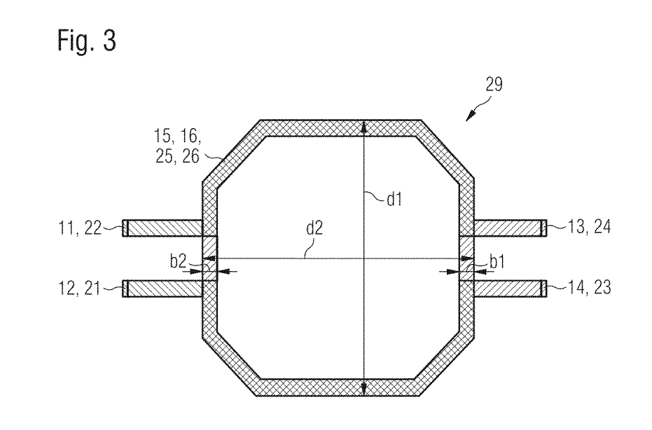

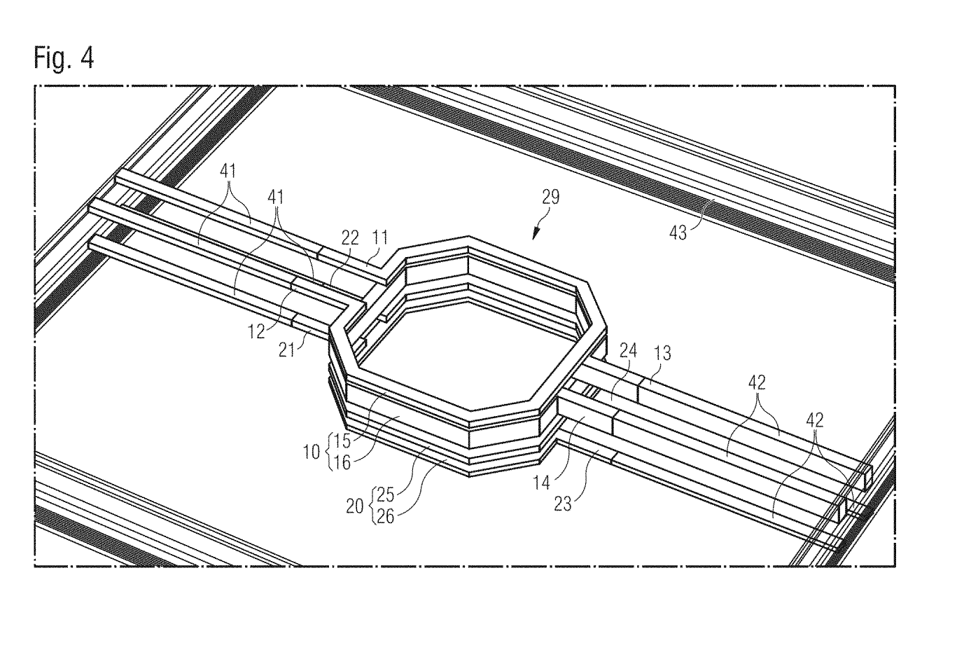

Using FIGS. 2A, 2B, 3 and 4, an embodiment of a differential directional coupler 29 will now be explained in greater detail. FIGS. 2A and 2B show diagrammatic perspective views of directional coupler 29 (FIG. 2A) and a section of directional coupler 29 (FIG. 2B). FIG. 3 shows a physical implementation of directional coupler 29. FIG. 4 shows a three dimensional representation of directional coupler 29 and, in particular, a possible embedment of directional coupler 29 in a chip system by means of a perspective view.

Directional coupler 29 may include a first coupler with a first transformer 10 and a second coupler with a second transformer 20. The first coupler and the second coupler may be in each case a single ended transformer based directional coupler such as, for example, a quadrature hybrid directional coupler. First transformer 10 may contain a first input coil 15 and a first output coil 16. Furthermore, second transformer 20 may contain a second input coil 25 and a second output coil 26. First input coil 15, first output coil 16, second input coil 25 and second output coil 26 may be based in each case on single metal layers which may be arranged following one another.

In particular, directional coupler 29 and/or an equivalent circuit of directional coupler 29 may be based on lumped elements. In this context and in the following, a “lumped element” may be an electrical component, the dimensions of which are less than 1/10 of a wavelength of the input signal Sᵢₙ, S_{in,ref}. For example, a lumped element is a resistor, a capacitor or an inductance.

The two input coils 15, 25 may each include an input port 11, 21 and a transmission port 12, 22. In an alternative embodiment, it is possible that the two input coils 15, 25 each include a plurality of input ports 11, 21 and a plurality of transmission ports 12, 22. Furthermore, the two output coils 16, 26 may each include an insulation port 14, 24 and an output port 13, 23. For example, insulation ports 14, 24 are terminated with a resistor, particularly one matched to an impedance of directional coupler 29. For example, insulation ports 14, 24 are insulated from the respective input ports 11, 21.

In some embodiments, input coils 15, 25 and output coils 16, 26 may each be based on a wound conductor track. The conductor tracks may have a first width b1 and a second width b2. For example, a magnetic and/or a capacitive coupling between the conductor tracks, and thus between the individual input coils 15, 25 and output coils 16, 26 may be adjusted by means of the first width b1 and/or the second width b2. In particular, it is possible to adjust a phase shift between the input signal Sᵢₙ, S_{in,ref} and the first output signal Sₒᵤₜ₁, S_{out1,ref} and the second output signal Sₒᵤₜ₂, S_{out2,ref}, respectively, by means of the strength of the capacitive coupling between the first coupler and the second coupler. This may be done, for example, by correspondingly matching the first width b1 and/or the second width b2.

In some embodiments, the first transformer 10 may overlap the second transformer 20 in a top view of the differential directional coupler 29, and in particular, may overlap completely. In this context and in the text which follows, “the top view” is meant to be a view of the directional coupler 29 from a vertical direction which extends perpendicularly to a main plane of extent of the directional coupler 29. In other words, first transformer 10 and second transformer 20 are arranged above one another along the vertical direction, at least partially, in particular completely. For example, first transformer 10 and second transformer 20 are overlapped completely in the top view, within production tolerances. In particular, it is possible that the two transformers 10, 20 are designed to have the same shape. The two transformers 10, 20 and, in particular, input coils 15, 25 and output coils 16, 26 may have the same size.

Input coils 15, 25 and output coils 16, 26 may be stacked alternately above one another. Between input coils 15, 25 and output coils 16, 26, an insulating material may be arranged in each case.

The two transformers 10, 20 may cover a chip area. The size of the chip area may be determined essentially by a first diameter d1 and a second diameter d2, extending transversely, particularly perpendicularly to the first diameter d1 (compare, for example, FIG. 3 in this respect). Due to the arrangement of the two transformers 10, 20 above one another, it is possible that the covered chip area is relatively small. In particular, the chip area may correspond to an area covered by first input coil 15, second input coil 25, first output coil 16 or second output coil 26. For example, the first diameter d1 and the second diameter d2, in a directional coupler 29 which is provided for a frequency of the differential input signal Sᵢₙ, S_{in,ref} of about 10 GHz to 100 GHz, in each case correspond to at least 50 μm and at the most 100 μm, particularly 68 μm. The chip area may then be, for example, essentially 68 μm×68 μm.

First input coil 15 and the second input coil 25 may be designed to be mirror symmetric with respect to one another with respect to the input ports 11, 21 transmission ports 12, 22 in the top view. In particular, input port 11 and transmission port 12 of first input coil 15 may be arranged exchanged relative to input port 21 and transmission port 22 of second input coil 25.

In particular, it is possible that the first and second couplers are in each case single ended directional couplers, for example single ended quadrature hybrid directional couplers. For example, the first coupler implements a directional coupler having a (0°, 90°) phase output and the second coupler implements a directional coupler having a (180°, 270°) phase output.

The first and second couplers may be arranged stacked above one another and capacitively coupled to one another in order to implement differential directional coupler 29. In particular, the first coupler and the second coupler may be arranged above one another in such a manner that a magnetic coupling between the two couplers is always positive. A positive magnetic coupling may be given in this connection and in the following when a mutual inductance or a counter inductance of the two couplers is positive. In the case of a positive magnetic coupling, the magnetic fluxes of the first and second coupler are always superimposed positively, in particular. In other words, the magnetic fluxes add together. This may be implemented in that the input ports 11, 21 are arranged on a same side of differential directional coupler 29. Since the current of the reference signal S_{in,ref} flows in the reverse direction as that of the base signal Sᵢₙ, it may be required to exchange the input ports 11, 21 against one another in order to provide for the positive magnetic couplers.

In some embodiments, directional coupler 29 may be integrated on a chip, particularly a chip system. For example, directional coupler 29 is connected to a support system 43 by means of electrical feed lines 41, 42 for this purpose.

In some embodiments it is possible that differential directional coupler 29 is used in a signal conversion system which comprises the transmitter 50. For example, the transmitter 50 may be integrated in the same chip system as directional coupler 29. The base signal S in generated by means of transmitter 50 may be applied to input port 11 of the first coupler and the reference signal S_{in,ref} generated by means of transmitter 50 may be applied to input port 21 of the second coupler. The applying may take place, for example, by means of feed lines 41, 42 represented in FIG. 4.

The base signal Sᵢₙ may cause a base signal current I₁ in first input coil 15, the flux of which may generate a first magnetic field H₁ within first input coil 15 (compare, for example, FIG. 2A in this respect). Furthermore, the reference signal S_{in,ref} may cause a reference signal current I₂ in second input coil 25, the flux of which current I₂ may generate a second magnetic field H₂ within second input coil 25. The base signal current I₁ and the reference signal current I₂ can flow in the same direction, particularly always. For example, the base signal current I₁ and/or the reference signal current I₂ flow parallel to the main plane of extent and perpendicularly to the vertical direction from which the top view takes place, within production tolerances.

The first magnetic field H₁ and the second magnetic field H₂ may extend in such a manner that the first transformer 10 and the second transformer 20 are coupled positively to one another. In other words, the first magnetic field H₁ and the second magnetic field H₂ may add up positively to form a larger combined magnetic field or, respectively, the magnetic fluxes in the two transformers 10, 20 may become superimposed constructively. The two magnetic fields H₁, H₂ may effect a magnetic coupling between the input coils 15, 25 and the output coils 16, 26. As a result, it is possible, for example in conjunction with a capacitive coupling between the first input coil 15 and the first output coil 16 and a capacitive coupling between the second input coil 25 and the second output coil 26 to convert the differential input signal Sᵢₙ, S_{in,ref} into two differential output signals (not shown in FIGS. 2A, 2B and 3). The differential output signals may be tapped, for example, at the transmission ports 12, 22 and/or the output ports 14, 24.

Due to the oppositely phased course of the reference signal S_{in,ref} with respect to the base signal Sᵢₙ, the base signal current I₁ would run oppositely to the reference signal current I₂ with an alternative differential directional coupler in which the input ports 11, 21 and the transmission ports 12, 22 are not exchanged relative to one another. This would lead to a destructive superposition of the two magnetic fields H₁, H₂. To compensate for this effect, the input ports 11, 21 and the transmission ports 12, 22 may be exchanged with one another in order to provide for a constructive superposition of the two magnetic fields H₁, H₂, in particular.

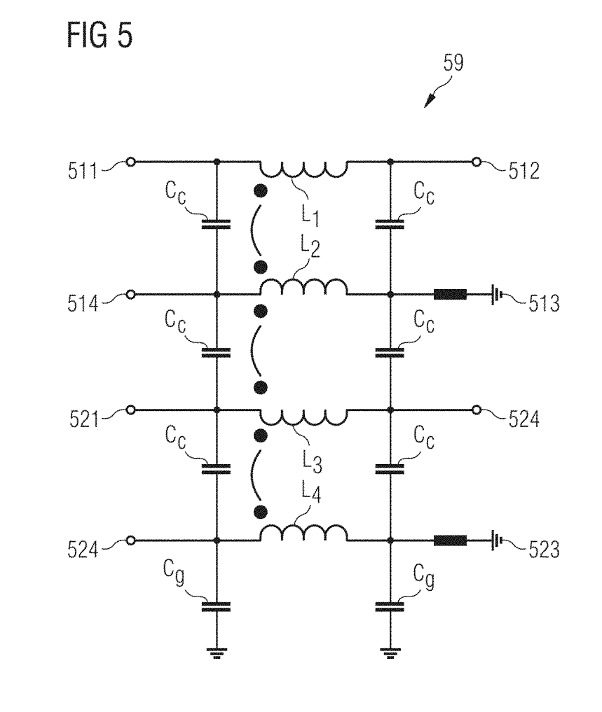

An embodiment of a directional coupler 59 described here is explained in greater detail by means of the equivalent circuit shown in FIG. 5. Directional coupler 59 may comprise a first input coil 515 having an input port 511 and a transmission port 512, a first output coil 516 having an output port 514 and an insulation port 513, a second input coil 525 having an input port 521 and a transmission port 522 and a second output coil 526 having an output port 523 and an insulation port 523.

Input coils 515, 525 and output coils 516, 526 may be coupled in each case magnetically (inductances L₁, L₂, L₃, L₄) and capacitively (capacitors C_{C}) to the respective adjacent input coils 515, 525 and output coils 516, 526, respectively. Input coils 515, 525 and output coils 516, 526 may each be based on a single, particularly metallic conductor track. The equivalent circuit shown may correspond to that of an equivalent of a Lange coupler based on concentrated elements.

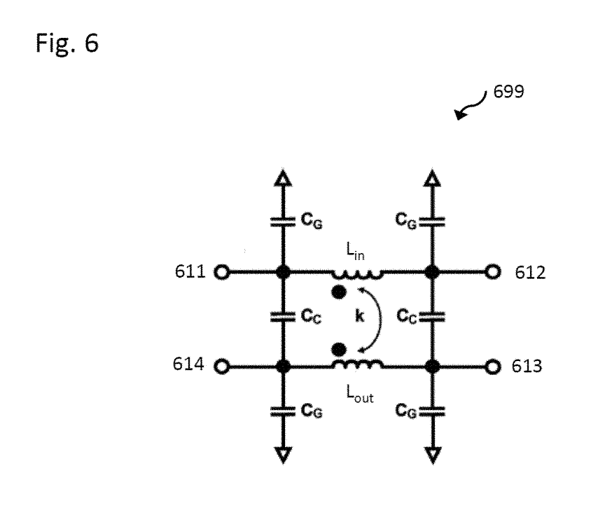

An embodiment of a differential directional coupler 29 described herein is explained in greater detail by means of the equivalent circuit, shown in FIG. 6, of a coupler 699. Coupler 699 may be the first coupler and/or the second coupler of the differential directional coupler 29, the coupler 699 here not being operated in conjunction with other couplers. The implementation shown in FIG. 6 is an extremely compact implementation of a coupler which may be based on an equivalent circuit which simulates the Lange coupler. In particular, coupler 699 may be designed to be single ended.

Coupler 699 may comprise a transformer having two coils Lᵢₙ, Lₒᵤₜ which are magnetically coupled to one another (coupling factor k). In addition, there may be a capacitive coupling between the coils via capacitors C_{C}. The coils Lᵢₙ, Lₒᵤₜ may be coupled to the environment via further capacitors C_{G}, particularly the substrate of the chip system. In particular, the further capacitors C_{G} may be parasitic capacitors. Alternatively to the embodiment shown in FIG. 6, the capacitors C_{C} and/or the further capacitors C_{G} may also assume different values in each case. Furthermore, the coupler 699 comprises an input port 611, a transmission port 612, a, particularly grounded, insulation port 613 and an output port 614.

In the case of similarly designed coils (Lᵢₙ=Lₒᵤₜ=L), the equivalent circuit, in the case of a fixed coupling factor k, may be described by means of the following formulae:

$$\begin{matrix}L = ( \frac{{Z}_{oe} + {Z}_{oo}}{2} ) \frac{1}{{ω}_{o}} sin {θ}_{o} ; & ( 1 ) \\ M = ( \frac{{Z}_{oe} - {Z}_{oo}}{2} ) \frac{1}{{ω}_{o}} sin {θ}_{o} ; & ( 2 ) \\ {C}_{G} = \frac{1}{{ω}_{o} {Z}_{oe}} tan \frac{{θ}_{o}}{2} ; & ( 3 ) \\ {C}_{C} = ( \frac{{Z}_{oe} - {Z}_{oo}}{2 {Z}_{oe} {Z}_{oo}} ) \frac{1}{{ω}_{o}} sin {θ}_{o} ; & ( 4 ) \\ {Z}_{o}^{2} = {Z}_{oe} {Z}_{oo} ; & ( 5 ) \\ {Z}_{oo} = 50 Ω \cdot \sqrt{\frac{1 - \frac{1}{\sqrt{2}}}{1 + \frac{1}{\sqrt{2}}}} \approx 20.71 Ω ; \\ {Z}_{oe} = 50 Ω \cdot \sqrt{\frac{1 + \frac{1}{\sqrt{2}}}{1 - \frac{1}{\sqrt{2}}}} \approx 120.71 Ω . & ( 6 )\end{matrix}$$

In this arrangement, Zₒₒ is the characteristic impedance of the odd mode, Zₒₑ the characteristic impedance of the even mode, Zₒ the characteristic wave impedance, ωₒ the angular frequency of the input signal, M the counter inductance and θₒ the electrical length of a corresponding transmission line. In this context and in the following a line may be a component, the dimensions of which are within the range of the wavelength of the input signal. To derive the aforementioned formulae, reference is made in this context to the document D. Ozis—“Integrated Quadrature Couplers and Their Application in Image-Reject Receivers”, IEEE Journal of Solid-State Circuits, Vol. 44, No. 5 (May 2009). At a frequency of 50 GHz, the following ideal values are obtained for coupler 699: L=187.57 pH; M=132.63 pH; C_{G}=21.975 fF; C_{C}=53.052 fF.

Coupler 699 may be suitable for converting single ended signals such as, for example, the base signal or the reference signal. With a corresponding extension of the coupler 699, a conversion of differential signals may also be possible, however.

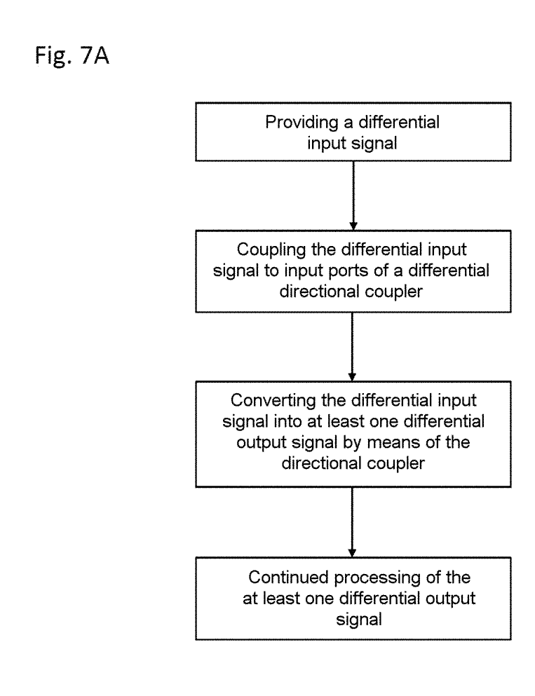

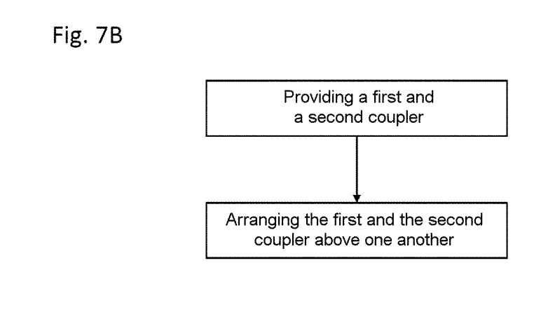

By means of FIG. 7A, a method, described here, for converting a differential input signal is explained in greater detail. In the method, a differential input signal Sᵢₙ, S_{in,ref} may be provided, for example, by means of the transmitter 50 which is coupled to input ports of a differential directional coupler 29, for example the input ports 11, 21 of the first and second coupler. The differential input signal Sᵢₙ, S_{in,ref} is converted, especially by means of the differential directional coupler 29, into at least one differential output signal Sₒᵤₜ₁, S_{out1,ref}, Sₒᵤₜ₂, S_{out2,ref} which may be processed further.

A method for providing a differential directional coupler 29 is explained in greater detail by means of FIG. 7B. In the method, a first coupler and a second coupler are provided. The first and second couplers may be the first and second couplers described in conjunction with FIGS. 1 to 4. In particular, the first coupler comprises a first transformer 10 comprising a first input coil 15 and a first output coil 16. The second coupler may include a second transformer 20 having a second input coil 25 and a second output coil 26. The method for providing the directional coupler also comprises arranging of the first coupler and of the second coupler above one another in such a manner that the first transformer 10 at least partially covers the second transformer 20 in a top view from a vertical direction onto the differential directional coupler 29.

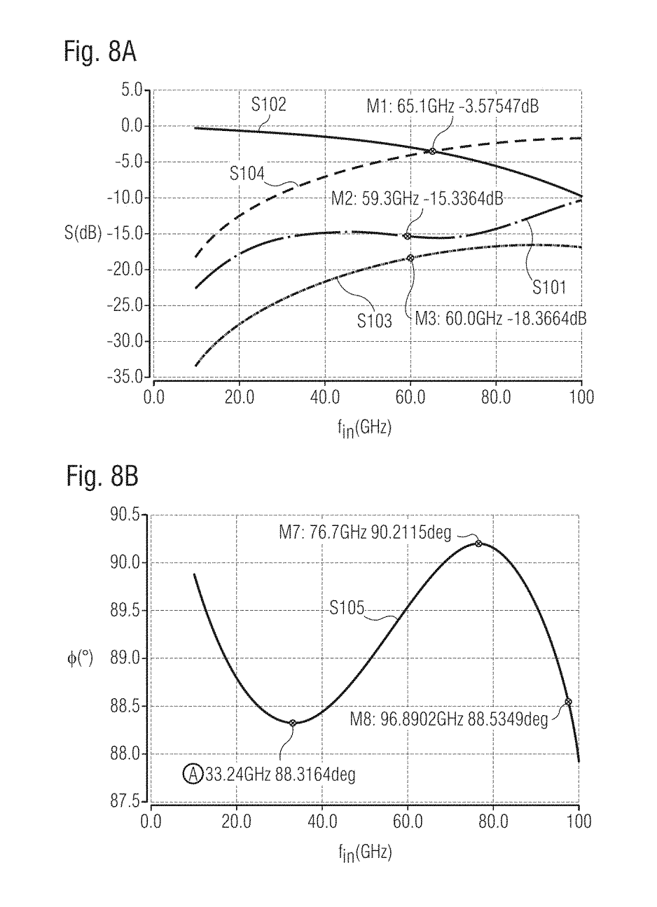

By means of FIGS. 8A and 8B an embodiment of a coupler 699 for a directional coupler 29 described here is explained in greater detail. Coupler 699 may be based on the embodiment shown in FIG. 6. In this context, an optimization for frequencies of the input signal Sᵢₙ, S_{in,ref} of at least 20 GHz and, at the most, 80 GHz, may have taken place, for example, by correspondingly adapting the first width b1 and/or the second width b2 and/or by means of the size of input coils 15, 25 and/or output coils 16, 26. In particular, coupler 699 may be a so called single ended coupler which, for example, can be provided for converting single ended signals.

FIG. 8A shows simulations of the S parameters S in dB as a function of the frequency fᵢₙ of an input signal Sᵢₙ, S_{in,ref} for a residual signal (of associated first S parameters S101) at input port 611, a transmission signal (associated second S parameter S102) at transmission port 612, an insulation signal (associated third S parameter S103) at insulation port 613 and an output signal (associated fourth S parameter S104) at output port 614. For the simulations of the S parameters, a 50Ω termination was presumed here in each case and also in the text which follows. Furthermore, FIG. 8B shows simulations S105 for a phase difference φ in ° of the output signal relative to the input signal. A single ended coupler based on concentrated elements may accordingly have a high bandwidth during the signal conversion. For example, the power of the output signal varies with a frequency change of 40 GHz (for example within the range of an input signal frequency of at least 40 GHz and, at the most, 80 GHz) by 5 dB at the most.

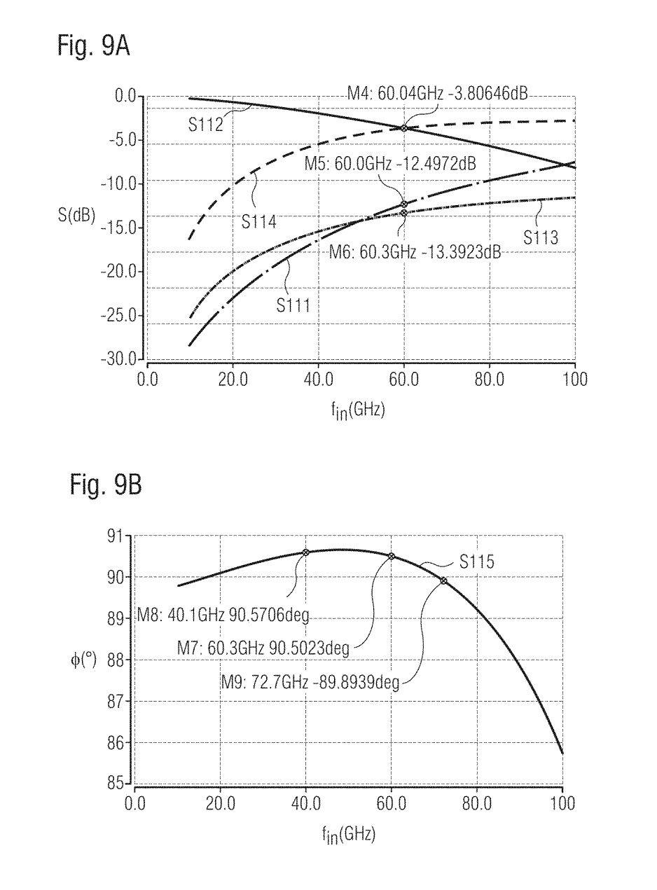

By means of FIGS. 9A and 9B, an embodiment of a differential directional coupler 29 is explained in greater detail. Differential directional coupler 29 may be used for converting a differential input signal Sᵢₙ, S_{in,ref}. For example, differential directional coupler 29 can contain at least one, preferably exactly two, single ended couplers 699. The differential directional coupler can be based on the embodiment shown in FIGS. 2A, 2B, 3 and 4 and/or in FIG. 5, wherein an optimization for frequencies of the differential input signal Sᵢₙ, S_{in,ref} of at least 20 GHz and, at the most, 80 GHz can take place. FIG. 9A shows simulations of the S parameters S in dB as a function of the frequency fᵢₙ of the differential input signal Sᵢₙ, S_{in,ref} for a differential residual signal, present at input ports 11, 21 (associated first S parameter Sill), the first differential output signal Sₒᵤₜ₁ present at transmission ports 12, 22 (associated second S parameter S112), the second differential output signal Sₒᵤₜ₂ present at output ports 14, 24 (associated fourth S parameter S114) and for the differential insulation signal at insulation port 13, 23 (associated third S parameter S113). FIG. 9B shows simulations S115 for a phase difference φ in ° between the first differential output signal Sₒᵤₜ₁ and the second differential output signal Sₒᵤₜ₂.

A directional coupler 29 described here may have a wide band coupling over a large frequency range, particularly a wide band power stability and a wide band phase stability. This can be made possible by, among other things, the use of concentrated elements. Through this, for example, a wide band quadrature hybrid coupler having a small size may be provided.

For example, the phase difference φ changes within the range of at least 20 GHz and, at the most, 80 GHz by a maximum of 2°, within the range of at least 20 GHz, particularly at least 30 GHz, and, at the most, 60 GHz by less than 1°. Furthermore, it is possible that the power of the first differential output signal Sₒᵤₜ₁ and/or of the second differential output signal Sₒᵤₜ₂ changes within a range of at least 20 GHz, particularly at least 30 GHz, and, at the most, 100 GHz by, at the most, 10 dB. Within the range of at least 40 GHz and, at the most, 80 GHz, the power of the first differential output signal Sₒᵤₜ₁ and/or of the second differential output signal Sₒᵤₜ₂ can change, in particular, by 5 dB at the most. The optimum operation of the directional coupler 29 can be at a frequency of about 60 GHz, particularly at least 59 GHz and, at the most, 62 GHz.

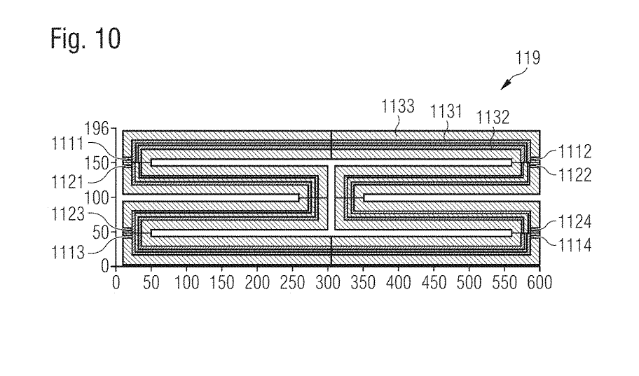

Using FIG. 10, an embodiment of an alternative differential directional coupler 119, which may be based on distributed elements, is explained in greater detail by means of a diagrammatic representation. The alternative differential directional coupler 119 may be designed as branch line coupler and particularly of one part or one piece. The alternative differential directional coupler 119 may be a coupler based on distributed elements, particularly on transmission lines or line pieces. Such a directional coupler may be dimensioned in a relatively simple manner but has the disadvantage that a high demand for space is required on the chip system or the chip, which increases with the wavelength of the input signal.

The alternative differential directional coupler 119 may have a first transmission line 1131 and a second transmission line having in each case an input port 1111, 1121, a transmission port 1112, 1122, an output port 1114, 1124 and an insulation port 1113, 1123. Furthermore, there is some metallization 1133 which extends underneath the lines of the directional coupler. The alternative differential directional coupler 119 may be a differential branch line coupler.

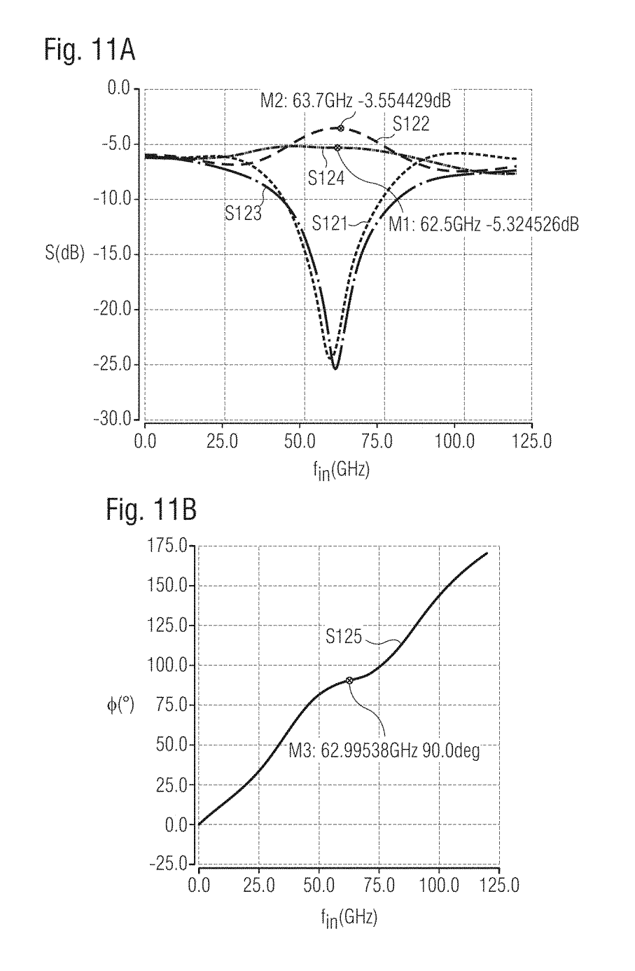

Using FIGS. 11A and 11B, an embodiment of an alternative differential directional coupler 119 is explained in greater detail. The figures show simulations of an alternative differential directional coupler 119 optimized for frequencies of the input signal within a range of at least 20 GHz and, at the most, 80 GHz. FIG. 11A shows simulations of the S parameters S in dB as a function of the frequency fᵢₙ of an input signal for a residual signal S121 at the input ports 1111, 1121, a transmission signal S122 at the transmission ports 1112, 1122, an insulation signal S123 at the insulation ports 1113, 1123, and an output signal S124 at the output ports 1114, 1124. Furthermore, FIG. 11B shows simulations S125 for a phase difference φ in ° of the output signal S124 relative to the input signal 121. An alternative differential directional coupler 119, which is based on distributed elements, may have a greatly frequency dependent coupling in comparison with a differential directional coupler 29 described here and can be designed, in particular, for narrow band conversion of the input signal. In particular, the alternative differential directional coupler 119 can have a 2 dB power inequality and a strong phase change over the frequency range.

According to at least one embodiment of a directional coupler, the latter comprises a first coupler with a first transformer and a second coupler with a second transformer. The first transformer comprises a first input coil and a first output coil. Furthermore, the second transformer comprises a second input coil and a second output coil. The first input coil and the second input coil, respectively, and the first output coil and the second output coil, respectively, can be in each case the transformer coils of the first transformer and of the second transformer, respectively. For example, the first input coil or the second input coil, respectively, can be coupled magnetically and/or capacitively to the first output coil or the second output coil, respectively.

The input coils and the output coils may be formed with electrically conductive conductor track windings. The conductor track windings can be designed, in particular, to be of one piece. It is possible that the input coils and the output coils comprise in each case only one conductor track winding. Alternatively, at least one of the input coils and/or at least one of the output coils have a number of conductor track windings.

According to at least one embodiment, the first input coil and the second input coil each comprise one input port. It is possible that the first and the second input coil, respectively, include further input ports. The input port may be an electrically conductive connection of the first and second input coil, respectively, which may be configured for coupling a signal into the first and second input coil, respectively.

According to at least one embodiment, the first transformer covers the second transformer in a top view from the vertical direction onto the differential directional coupler, at least partially. In other words, the first transformer and the second transformer may be arranged above one another. In other words, the first transformer and the second transformer are arranged along the vertical direction at least partially above one another. The vertical direction may extend perpendicularly to a main plane of extent in which the differential directional coupler extends in lateral directions. Perpendicularly to the main plane of extent, the directional coupler may have a thickness which is small compared with a maximum extent of the directional coupler in one of the lateral directions. For example, in operation of the directional coupler, a signal current flows which is generated by a signal applied to at least one of the input ports, in parallel with the main plane of extent within production tolerances.

According to at least one embodiment, the first input coil and the second input coil are designed to be mirror symmetric with respect to one another in the top view with respect to their input ports. A “mirror symmetric design” of ports such as, for example, the input ports, is to be understood in this context, and in the text which follows, not in the mathematically strict sense of the term but instead within production tolerances. The mirror symmetric design may be related, in particular, only, that is to say exclusively, to the position of the mirror symmetrically designed ports. For example, the ports are arranged exchanged with respect to their respective position in or at the associated input coil in the case of a mirror symmetric design. In other parts of the input coils such as, for example, conductor track windings, it may be possible that a mirror symmetric design is not required.

According to at least one embodiment, the first input coil and the second input coil each comprise a transmission port. It is possible that the first and the second input coil, respectively, have other transmission ports. For example, the respective input port of the first and of the second input coil, respectively, may be coupled to the respective transmission port via at least one conductor track winding of the respective input coil.

According to at least one embodiment, the first input coil and the second input coil are designed to be mirror symmetric with respect to one another in the top view with respect to their transmission ports. It is possible that the first input coil and the second input coil are designed mirror symmetrically with respect to one another in the top view with respect to their input ports and with respect to their transmission ports. In particular, the input port and the transmission port of the first input coil may be arranged to be exchanged relative to the input port and the transmission port of the second input coil. For example, exchanging the input port of the first input coil with the transmission port of the first input coil may transfer the first input coil into the second input coil and conversely.

According to at least one embodiment, the input port of the first coupler at least partially covers the transmission port of the second coupler in the top view. Furthermore, the transmission port of the first coupler at least partially covers the input port of the second coupler in the top view. In particular, the input port and the transmission port, respectively, of the first coupler may cover the transmission port and the input port, respectively, of the second coupler in each case completely in the top view.

According to at least one embodiment of the differential directional coupler, the first coupler and the second coupler are designed to be electrically insulated from one another. Furthermore, the differential directional coupler is designed to be sectionalized. For example, an electrically insulating material is arranged in each case between the first input coil, the first output coil, the second input coil and the second output coil.

According to at least one embodiment of the differential directional coupler, the first coupler and the second coupler are in each case based on concentrated elements. For example, the differential directional coupler is formed, especially exclusively, from concentrated elements. In particular, a concentrated element has dimensions or a size, respectively, which is less than 1/10 of a wavelength of the input signal. Alternatively or additionally, the first coupler and the second coupler may be in each case single ended transformer based directional couplers. A single ended directional coupler may be provided for converting a single ended signal. For example, it is possible, as a result, to provide a particularly compact directional coupler. In contrast thereto, couplers having distributed elements such as, for example, couplers based on transmission lines, exhibit a greater extension.

According to at least one embodiment of the differential directional coupler, the first coupler and the second coupler have the same shape. For example, the first input coil and the second input coil or the first output coil and the second output coil, respectively, have the same number of conductor track windings and the same coil radius.

According to at least one embodiment of the differential directional coupler, the first transformer and the second transformer are arranged coincidentally above one another in the top view within the scope of the production tolerances. In other words, the first transformer completely covers the second transformer and conversely.

According to at least one embodiment, the first coupler and the second coupler are in each case quadrature hybrid directional couplers. Alternatively or additionally, the differential directional coupler is a differential quadrature hybrid directional coupler. In other words, the first coupler and the second coupler and/or the differential directional coupler may be configured in each case to convert an incoming signal into two outgoing signals which have the same power within production tolerances and have a 90° phase shift with respect to one another.

According to at least one embodiment, the first output coil and the second output coil each have an insulation port and an output port. The respective insulation port may be coupled to the respective output port via a conductor track winding of the respective output coil. The first output coil and the second output coil are designed to be mirror symmetric with respect to one another in the top view with respect to their insulation ports and their output ports.

According to at least one embodiment, the first transformer and the second transformer cover a chip area in the top view which is, at the most, 120%, preferably at the most no % and particularly preferably at the most 105% of the area covered by the first or the second transformer. In other words the differential directional coupler can have the size of the first or of the second coupler, within the scope of the production tolerances, particularly of the first input coil, of the second input coil, of the first output coil or of the second output coil.

According to at least one embodiment, a signal conversion system comprises a transmitter which is configured to generate a differential input signal having a base signal and a reference signal. The reference signal is of opposite phase, that is to say phase shifted by 180°, with respect to the base signal. In particular, the differential input signal can have an input signal frequency. For example, the input signal frequency is at least 500 MHz and, at the most, 300 GHz, preferably at least 10 GHz and, at the most, 100 GHz.

According to at least one embodiment, the signal conversion system comprises a differential directional coupler. The differential directional coupler may comprise a first coupler having a first transformer and a second coupler having a second transformer.

The transmitter and the differential directional coupler can be mounted on the same chip system. Furthermore, it is possible that the transmitter is configured for receiving a signal which is generated outside the chip system and converts the signal into the differential input signal.

According to at least one embodiment of the signal conversion system, the base signal is coupled to an input port of the first coupler. Furthermore, the reference signal is coupled to an input port of the second coupler. For example, the coupling is effected via connecting lines by means of which a signal output of the signal conversion system is connected electrically conductively to the input ports.

According to at least one embodiment, the differential directional coupler is configured to convert the differential input signal at least partially into at least one differential output signal having a phase shift with respect to the differential input signal. The at least one differential output signal may contain a phase shifted base signal and a phase shifted reference signal designed to have the opposite phase to the phase shifted base signal. The phase shifted reference signal can have the phase shift with respect to the phase shifted base signal and the output reference signal can have the phase shift with respect to the reference signal. For example, the differential directional coupler is configured to split the differential input signal into two differential output signals. Alternatively or additionally, it is possible that the differential directional coupler is configured to combine the differential input signal with a further, particularly differential, signal.

According to at least one embodiment, a base signal current of the base signal through the first transformer generates a first magnetic field and a reference signal current of the reference signal through the second transformer generates a second magnetic field. The input ports of the first and second coupler are arranged relative to one another in such a manner that the first magnetic field and the second magnetic field are superimposed constructively. A constructive superposition is generated, for example, with the coupling of two coils in the same sense. A coupling in the same sense is provided for, for example, by a positive magnetic coupling in which the magnetic fields add together positively.

According to at least one embodiment, the first transformer comprises a first input coil and a first output coil and the second transformer comprises a second input coil and a second output coil. The first input coil and the first output coil and/or the second input coil and the second output coil are magnetically and/or capacitively coupled. This coupling can serve to convert the differential input signal into the differential output signal.

According to at least one embodiment, the phase shift of the at least one differential output signal can be adjusted by means of a first width of at least one conductor track of the first transformer and/or by means of a second width of at least one conductor track of the second transformer. For example, the intensity of the capacitive and/or a magnetic coupling between the first input coil and the first output coil or between the second input coil and the second output coil, respectively, may be influenced by means of the first width and/or the second width. Alternatively or additionally, it is possible that the capacitive and/or the magnetic coupling may be adjusted by means of a distance between the conductor tracks.

According to at least one embodiment, the differential directional coupler is configured to convert the differential input signal into a first differential output signal having a first phase shift with respect to the differential input signal and a second differential output signal having a second phase shift with respect to the differential input signal. The first phase shift may be 0° and the second phase shift may be 90°. Alternatively or additionally, the power of the first output signal may correspond to the power of the second output signal within production tolerances. The differential directional coupler may then be, for example, a differential quadrature hybrid coupler.

According to at least one embodiment, a winding direction of the first input coil is opposite a winding direction of the second input coil. In other words, the first input coil and the second input coil can be wound in such a manner that one of the two input coils is designed to be right handed and the other one of the two input coils is designed to be left handed or conversely. It is also possible that a winding direction of the first output coil is opposite a winding direction of the second output coil.

According to at least one embodiment, the first transformer and the second transformer cover a chip area in the top view. The chip area is in this embodiment 20%, at the most, preferably 10% at the most and particularly preferably 5% at the most, of the wavelength of the differential input signal.

According to at least one embodiment of a method for converting a differential input signal, the latter comprises providing a transmitter and providing a differential directional coupler. The differential directional coupler comprises a first coupler having a first input coil and a first output coil and a second coupler having a second input coil and a second output coil. Furthermore, the method comprises generating a differential input signal with the transmitter. The differential input signal comprises a base signal and a reference signal of the opposite phase to the base signal. The method also comprises converting the differential input signal into at least one differential output signal using the differential directional coupler.

According to at least one embodiment, the method comprises coupling the base signal to an input port of the first coupler and coupling the reference signal to an input port of the second coupler. The coupling is effected in such a manner that a base signal current of the base signal flows within the first input coil and a reference signal current of the reference signal flows within the second input coil in the same direction.

According to at least one embodiment, the converting of the differential output signal includes magnetic and/or capacitive coupling of the first input coil to the first output coil and magnetic and/or capacitive coupling of the second input coil to the second output coil. For example, the respective magnetic and/or capacitive coupling occurs by applying the differential input signal.

According to at least one embodiment, the converting of the differential output signal includes converting the base signal into a first and a second phase shifted base signal by means of the first coupler, converting the reference signal into a first and a second phase shifted reference signal using the second coupler, combining the first phase shifted base signal and the first phase shifted reference signal to form a first differential output signal and combining the second phase shifted base signal and the second phase shifted reference signal to form a second differential output signal.

According to at least one embodiment, the method comprises performing a modulation method using the first differential output signal and the second differential output signal. For example, a quadrature amplitude modulation is performed.

According to at least one embodiment, providing the differential directional coupler takes place in such a manner that the first input coil and/or the first output coil are arranged to be coincident above the second input coil and/or the second output coil in a top view of the differential directional coupler, within the scope of the production tolerances. In particular, it is possible that the first input coil covers the first output coil, the second input coil and the second output coil.

According to at least one embodiment of the method, providing the differential directional coupler takes place in such a manner that a magnetic coupling between the first coupler and the second coupler is positive. For example, the input coils and the output coils are arranged in such a manner with respect to one another that a base signal current of the base signal flows oppositely to a reference signal current of the reference signal.

Although this invention has been described with reference to illustrating embodiments, the invention is not restricted by the description by means of the illustrative embodiments to these embodiments. Instead, the invention comprises every new feature and every combination of features which, in particular, also includes every combination of features in the patent claims even if this feature or this combination itself is not specified explicitly in the patent claims or embodiments. In particular, features can be represented in the drawings which are not mandatorily necessary for the implementation. Instead, in other embodiments, some of the features or elements shown or described may be omitted and/or replaced by alternative features or elements.

What is claimed is:

1. A differential directional coupler comprising:
a first coupler having a first transformer comprising a first input coil and a first output coil; and
a second coupler having a second transformer comprising a second input coil and a second output coil, wherein
the first input coil and the second input coil each include an input port,
the first transformer at least partially covers the second transformer in a top view from a vertical direction onto the differential directional coupler, and
the first input coil and the second input coil are configured to be mirror symmetric with respect to one another in the top view with respect to their input ports.

2. The differential directional coupler according to claim 1, wherein
the first input coil and the second input coil each include a transmission port and; and
the first input coil and the second input coil are designed to be mirror symmetric with respect to one another in the top view with respect to their transmission ports.

3. The differential directional coupler according to claim 2, wherein
the input port of the first coupler at least partially covers the transmission port of the second coupler in the top view; and
the transmission port of the first coupler at least partially covers the input port of the second coupler in the top view.

4. The differential directional coupler according to claim 1, wherein
the first coupler and the second coupler are electrically insulated from one another and the differential directional coupler is configured to be sectionalized.

5. The differential directional coupler according to claim 1, wherein
the first coupler and the second coupler are each based on concentrated elements and/or are each single ended transformer based directional couplers.

6. The differential directional coupler according to claim 1, wherein the first coupler and the second coupler have a same shape.

7. The differential directional coupler according to claim 1, wherein the first transformer and the second transformer are arranged coincidentally above one another in the top view within production tolerances.

8. The differential directional coupler according to claim 1, wherein:
the first coupler and the second coupler each comprise a quadrature hybrid directional couplers; and
the differential directional coupler is a differential quadrature hybrid directional coupler.

9. The differential directional coupler according to claim 1, wherein
the first output coil and the second output coil also each include an insulation port and an output port; and
the first output coil and the second output coil are mirror symmetric with respect to one another in the top view with respect to their respective insulation ports and their respective output ports.

10. The differential directional coupler according to claim 1, wherein
the first transformer and the second transformer cover a chip area in the top view; and
the chip area is, at most, one-hundred and twenty percent of the chip area covered by the first transformer or the second transformer.

11. A signal conversion system comprising
a transmitter which is configured to generate a differential input signal having a base signal and a reference signal of opposite phase with respect to the base signal; and
a differential directional coupler comprising a first coupler having a first transformer and a second coupler having a second transformer, wherein
the base signal is coupled to an input port of the first coupler,
the reference signal is coupled to an input port of the second coupler,
the differential directional coupler is configured to convert the differential input signal at least partially into at least one differential output signal having a phase shift with respect to the differential input signal,
a base signal current of the base signal through the first transformer generates a first magnetic field and a reference signal current of the reference signal through the second transformer generates a second magnetic field, and
the input ports of the first and second coupler are arranged relative to one another in such a manner that the first magnetic field and the second magnetic field are superimposed constructively.

12. The signal conversion system according to claim 11, wherein
the first transformer comprises a first input coil and a first output coil;
the second transformer comprises a second input coil and a second output coil; and
the first input and output coils, or the second input and output coils are magnetically or capacitively coupled for converting the differential input signal into the at least one differential output signal.

13. The signal conversion system according to claim 11, wherein the phase shift of the at least one differential output signal is adjustable via a first width of at least one conductor track of the first transformer or is adjustable via a second width of at least one conductor track of the second transformer.

14. The signal conversion system according to claim 11, wherein
the differential directional coupler is configured to convert the differential input signal into a first differential output signal having a first phase shift with respect to the differential input signal and into a second differential output signal having a second phase shift with respect to the differential input signal; and
the first phase shift is 0° and the second phase shift is 90°.

15. The signal conversion system according to claim 11, wherein
the differential directional coupler is configured to convert the differential input signal into a first differential output signal having a first phase shift with respect to the differential input signal and a second differential output signal having a second phase shift with respect to the differential input signal; and
a power of the first differential output signal corresponds to a power of the second differential output signal within production tolerances.

16. The signal conversion system according to claim 11, wherein
the first transformer includes a first input coil;
the second transformer includes a second input coil; and
a winding direction of the first input coil is opposite a winding direction of the second input coil.

17. The signal conversion system according to claim 11, wherein
the first transformer and the second transformer cover a chip area in a top view; and
the chip area is, at most, twenty percent of a wavelength of the differential input signal.

18. A method for converting a differential input signal, the method comprising:
providing a transmitter;
providing a differential directional coupler comprising a first coupler with a first input coil and a first output coil, and a second coupler having a second input coil and a second output coil;
generating the differential input signal with the transmitter, wherein the differential input signal comprises a base signal and a reference signal of an opposite phase to the base signal;
coupling the base signal to an input port of the first coupler and coupling the reference signal to an input port of the second coupler, in such a manner that a base signal current of the base signal flows within the first input coil and a reference signal current of the reference signal flows within the second input coil in a same direction; and
converting the differential input signal into at least one differential output signal using the differential directional coupler.

19. The method according to claim 18, wherein the converting of the at least one differential output signal includes:
magnetic or capacitive coupling of the first input coil to the first output coil; and
magnetic or capacitive coupling of the second input coil to the second output coil (26).

20. The method according to claim 18, wherein the converting of the differential output signal comprises:
converting the base signal into a first phase shifted base signal and a second phase shifted base signal using the first coupler;
converting the reference signal into a first phase shifted reference signal and a second phase shifted reference signal using the second coupler;
combining the first phase shifted base signal and the first phase shifted reference signal to form a first differential output signal; and
combining the second phase shifted base signal and the second phase shifted reference signal to form a second differential output signal.

21. The method according to claim 20, further comprising performing a modulation method using the first differential output signal and the second differential output signal.

22. The method according to claim 18, wherein the first input coil or the first output coil are arranged to be coincident above the second input coil or the second output coil in a top view of the differential directional coupler within production tolerances.

23. The method according to claim 18, wherein a magnetic coupling between the first coupler and the second coupler is positive.
